(19) United States
(12) Patent Application Publication
(10) Pub. No.: US 2006/0133440 A1
(43) Pub. Date: Jun. 22, 2006

(54) Optical semiconductor device

(76) Inventors: Ki Soo Kim, Daejeon (KR); Chul Wook Lee, Daejeon (KR); Dong Hun Lee, Daejeon (KR); Jung Ho Song, Daejeon (KR); Eun Deok Sim, Daejeon (KR); Sung Bock Kim, Daejeon (KR); Yong Soon Baek, Daejeon (KR)

Correspondence Address: LADAS & PARRY LLP, 224 SOUTH MICHIGAN AVENUE, SUITE 1600, CHICAGO, IL, 60604, US

(21) Appl. No.: 11/170,813

(22) Filed: Jun. 30, 2005

(30) Foreign Application Priority Data
Dec. 16, 2004 (KR) 2004-107030

(51) Int. Cl. H01S 5/20

(52) U.S. Cl. 372/45.01

(57) ABSTRACT

Provided is an optical semiconductor device including: an active layer having at least one quantum well layer and at least one barrier layer; a clad layer formed adjacent to the active layer; and a tunneling barrier layer formed between the active layer and the clad layer to be connected to the quantum well layer and formed of a material having a band-gap energy larger than the barrier layer, whereby it is possible to improve the drive characteristics at a high temperature and a high drive current by increasing a confinement effect of carriers such as electrons and holes in the active layer.

### CROSS-REFERENCE TO RELATED APPLICATION

This application claims priority to and the benefit of Korean Patent Application No. 2004-107030, filed Dec. 16, 2004, the disclosure of which is incorporated herein by reference in its entirety.

### BACKGROUND

1. Field of the Invention

The present invention relates to an optical semiconductor device and, more particularly, to an optical semiconductor device including an active layer having a quantum wall layer and a barrier layer, a clad layer, and a tunneling barrier formed to be connected to the quantum well layer using a material having a band-gap energy larger than the barrier layer, whereby it is possible to increase a confinement effect of carriers such as electrons and holes in the active layer and therefore to improve the driving characteristics at a high temperature and a high drive current.

2. Discussion of Related Art

In general, due to an inherent characteristic and un-optimized device structure of an optical semiconductor material, a confinement effect of carriers is reduced in an active layer region of an optical semiconductor device operating at a high temperature, and the carriers are unintentionally leaked to a separated confinement heterostructure (SCH) layer used as a barrier layer or a guide layer to emit light, thereby degrading the characteristics of the optical semiconductor device at a high temperature.

Hereinafter, among the optical semiconductor devices, a semiconductor laser diode including the SCH layer will be described in order to explain the aforementioned problems.

In the semiconductor laser diode, as is well known, in order to allow optical field and confinement of the carriers to be generated at different regions from each other and simultaneously to increase an optical confinement effect, an SCH structure that one semiconductor material or a plurality of semiconductor materials having a stepped shape, which have a band gap larger than that of the active layer and a refractive index smaller than that of the active layer, are deposited on both sides of the active layer is adapted to obtain high quantum efficiency.

In addition, when a 2-dimensional quantum well is used as a material forming the active layer rather than a 3-dimensional bulk, it is possible to obtain laser oscillating characteristics even at a lower threshold current since its density of state becomes low, and to manufacture a high efficiency semiconductor laser diode since its characteristic temperature becomes high.

Recently, as construction of an optical access network for optical communication has become an important issue in an information industry, it is required to manufacture a semiconductor laser diode for a long wavelength (1.3 μm, 1.55 μm) not sensitive to a temperature, and having a low threshold current and a high optical output characteristic even at a temperature of not less than 85° C., as an essential technology. However, although the optical device has been manufactured utilizing already known structural advantages in order to accomplish the abovementioned objects, it is so far difficult to implement the optical device having an excellent optical output characteristic at a high temperature and a high drive current.

The basic reason for this is that the materials most widely used as a material of an InGaAsP/InGaAs/InP or AlInGaAs/InP-based long wavelength semiconductor light emitting device have a band-offset of a conduction band smaller than that of a valence band, a small effective mass of an electron, and a relatively larger effective mass of a hole, when forming a heterojunction due to its intrinsic characteristic. As a result, the movement of the electron is easy and the movement of the hole is difficult. Therefore, as the temperature is increased, the movement of the carriers is severely varied depending on the temperature, and distribution of the carriers in the active layer becomes irregular to thereby degrade the characteristics of the optical device.

Typical phenomenon of characteristic degradation of the optical device is as follows: for example, in the case of the semiconductor laser diode, a threshold current value is increased, and an optical output is decreased due to an increase of internal loss.

Hereinafter, the problems of the conventional art will be described in conjunction with FIGS. 1 to 3. FIG. 1 is a cross-sectional view of an epitaxial structure of a conventional semiconductor laser diode and an energy band diagram of a semiconductor laser diode structure corresponding to the cross-sectional view.

The epitaxial structure of the semiconductor laser diode includes: an active layer 30 having quantum well layers 31, 33 and 35, and barrier layers 32 and 34; SCH layers 20 and 40 serving as guide layers of an optical field disposed at both sides of the active layer 30; and an n-type clad layer 10 and a p-type clad layer 50 disposed at both ends of the SCH layers to serve as injection passages of electrons and holes and to assist the confinement of the optical field.

While not shown in FIG. 1, an ohmic contact layer is grown after forming the p-type clad layer 50. Conventionally, the clad layers 10 and 50 should be made of a material having a band gap energy value larger and a refractive index smaller than that of the SCH layers 20 and 40 serving as a guide layer of the optical field. In addition, the band gap energy of a single SCH layer or a plurality of stepped SCH layers 20 and 40 should have a band gap energy value equal to or larger than that of a barrier layer of a quantum well.

FIG. 2 is a graph representing behavior of carriers shown as the energy band diagram of the semiconductor laser diode in FIG. 1. In FIG. 2, τᵣ represents emissive recombination, and τₙᵣ represents non-emissive recombination. Referring to FIG. 2, electrons should emit light within a quantum well layer as the active layer 30, however, some of the electrons spill-over the quantum well layer to be leaked to the p-type clad layer 50, in this process, some of the electrons are recombined with holes existing in the SCH layer 40 in an emissive or non-emissive manner, thereby increasing loss of electrons. As shown in FIG. 3, as a temperature increases and an injection current increases, this phenomenon becomes more severe.

FIG. 3 is a graph representing an energy band diagram and behavior of carriers when a temperature is increased at the semiconductor laser diode of FIG. 1. Dotted lines represent original energy band diagrams, and solid lines represent energy band diagrams varied by increase of temperature and irregular distribution of carriers.

Referring to FIG. 3, since a conduction band and a valence band sag downward when the temperature is increased, the electrons are more leaked in the direction of the p-clad layer 50 due to weakening of binding power into the active layer 30, on the contrary, in the case of the holes, a hetero-barrier layer for blocking the movement of the holes into the quantum well is newly formed between the barrier wall of the quantum well and the SCH layer. Especially, since the holes have an effective mass larger than that of the electrons, a large number of holes are trapped in the SCH layer without easily going over the newly formed hetero-barrier to allow non-emissive or emissive recombination in the SCH layer to be more severed in comparison with the case of a low temperature, thereby generally degrading performance of the semiconductor laser diode at a high temperature and a high drive current.

In order to overcome the aforementioned problems, various methods have been proposed. However, in most cases, the methods are a method of preventing electrons from being leaked to the p-clad layer to improve the characteristics, or methods that loss due to the emissive or non-emissive recombination in the SCH layer and the barrier layer is not considered, several of which will be described as follows.

P. Abraham et al. have attempted to perform technology that an In0.8Ga0.2P layer having a band gap energy larger than that of InP is epitaxially grown to less than the critical thickness to be formed between a p-InP clad layer and an InGaAsP SCH layer to prevent leakage of electrons into the p-clad layer to thereby improve the characteristics. However, a threshold current has not been decreased, while internal quantum efficiency is somewhat increased depending on a temperature (10^{th} Intern. Conf. On Indium Phosphide and Related Materials, Tsukuba, Japan pp. 713-716 (1998)). The reason for this is that the emissive or non-emissive recombination in the SCH layer occupying most of losses without being confined in the quantum well has not been considered, while the technology would limit a predetermined part of leakage of electrons.

Meanwhile, Korean Patent Laid-open Publication No. 2003-58419 discloses a method of forming an SCH layer made of InGaAsP materials having two different compositions in a stepped manner, and then inserting a highly doped p-InP layer to a thickness of about 10 nm between the two materials to prevent a barrier wall of electrons from relatively lowering at a high temperature and/or a high drive current, thereby preventing leakage of the electrons. However, this method also did not consider losses generated from a predetermined SCH layer still existing between a p-InP insert layer and a quantum well.

A. Ubukata et al. disclosed a method in which carrier blocking layers are inserted into SCH layers of a p-clad layer and an n-clad layer in an InGaAs/InGaAsP system to prevent leakage of electrons into the p-clad layer and leakage of holes into the n-clad layer at Jpn. J. Appl. Phys. Vol. 38, pp 1243-1245 (1999) and Korean Patent Laid-open Publication No. 2000-69016. It is also appreciated that the carrier blocking layer does not prohibit introduction of carriers into the quantum well through a simulation. However, in the case of this technology, since the holes have a very large effective mass, it is not likely to be reversely leaked into an n-clad region over the quantum well, and it is not advantageous to form the carrier blocking layer of the n-clad layer.

However, in this technology, the barrier layer or the SCH layer of a predetermined quantum well is still existing between the quantum well layer and the carrier blocking layer, therefore, it is impossible to avoid loss due to the emissive or non-emissive recombination of the carriers.

In addition, while various attempts such as a method of forming a multi-quantum barrier layer in an SCH layer (Appl. Phys. Lett. Vol. 72, pp. 2090˜2092 (1998)), or a method of forming a multi-quantum barrier layer in a p-clad layer (Korean Patent Registration No. 1997-54986) have been proposed to prevent the leakage of the electrons, it has also not considered optical losses generated due to the SCH layer still existing between an active layer and the multi-quantum barrier layer.

### SUMMARY OF THE INVENTION

The present invention is directed to a high efficiency semiconductor device capable of preventing leakage of carriers, and having a high optical output and a low threshold current at a high temperature and a high drive current since emission is mostly performed within a quantum well layer only.

One aspect of the present invention is to provide an optical semiconductor device including: an active layer having at least one quantum well layer and at least one barrier layer; a clad layer formed adjacent to the active layer; and a tunneling barrier layer formed between the active layer and the clad layer to be connected to the quantum well layer and formed of a material having a band-gap energy larger than the barrier layer.

An “optical semiconductor device” generally designates a device having an active layer and a clad layer to generate light, for example, a semiconductor laser diode, a semiconductor light emitting diode or the like. Preferably, the semiconductor laser diode includes a buried heterostructure (BH) laser diode, a ridge laser diode, a spot size converter or the like.

The tunneling barrier layer may be formed of a semiconductor layer, preferably, has a thickness of 1˜15 nm, and the band gap energy of the tunneling barrier wall may be equal to or smaller than that of the clad layer.

Another aspect of the present invention is to provide an optical semiconductor device including: an active layer having at least one quantum well layer and at least one barrier layer; an SCH layer and a clad layer formed adjacent to the active layer; and a tunneling barrier layer formed between the active layer and the SCH layer to be connected to the quantum well layer and formed of a material having band-gap energy larger than the SCH layer.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 is a cross-sectional view of a conventional semiconductor laser diode and an energy band diagram of a semiconductor laser diode structure corresponding to the cross-sectional view;

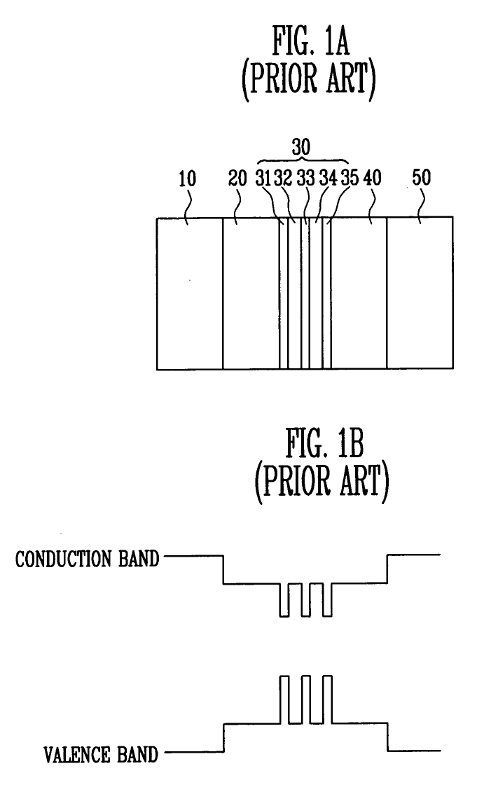

FIG. 2 is a graph representing behavior of carriers shown as the energy band diagram of the semiconductor laser diode in FIG. 1;

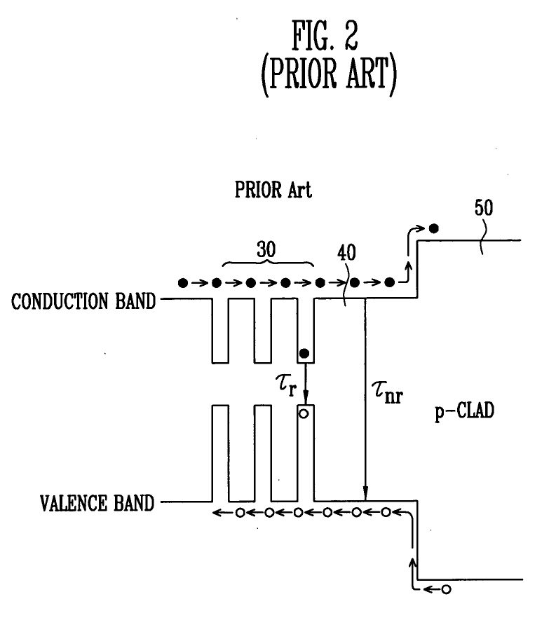

FIG. 3 is a graph representing an energy band diagram and behavior of carriers when a temperature is increased at the semiconductor laser diode of FIG. 1;

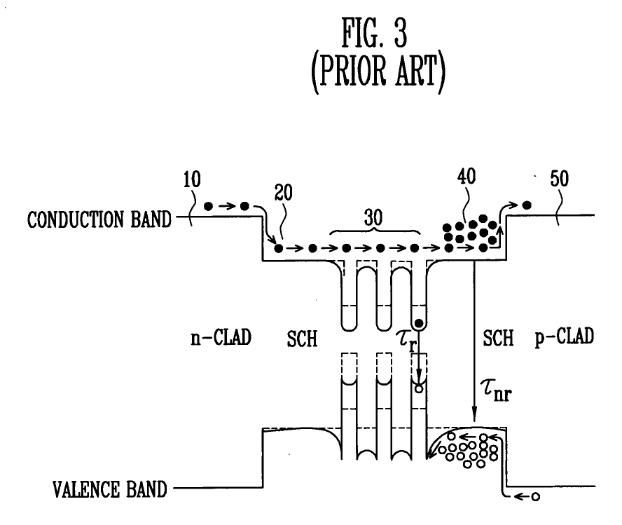

FIG. 4 is a cross-sectional view of a conventional semiconductor laser diode in accordance with a first embodiment of the present invention and an energy band diagram of a semiconductor laser diode corresponding to the cross-sectional view;

FIG. 5 is a graph representing behavior of carriers shown as the energy band diagram of the semiconductor laser diode in FIG. 4; and

FIG. 6 is a cross-sectional view of a conventional semiconductor laser diode in accordance with a second embodiment of the present invention and an energy band diagram of a semiconductor laser diode corresponding to the cross-sectional view.

### DETAILED DESCRIPTION OF PREFERRED EMBODIMENTS

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. Especially, in embodiments, an InP-based InP/InGaAs/InGaAsP semiconductor laser diode including an SCH layer of an optical semiconductor device will be described.

### Embodiment 1

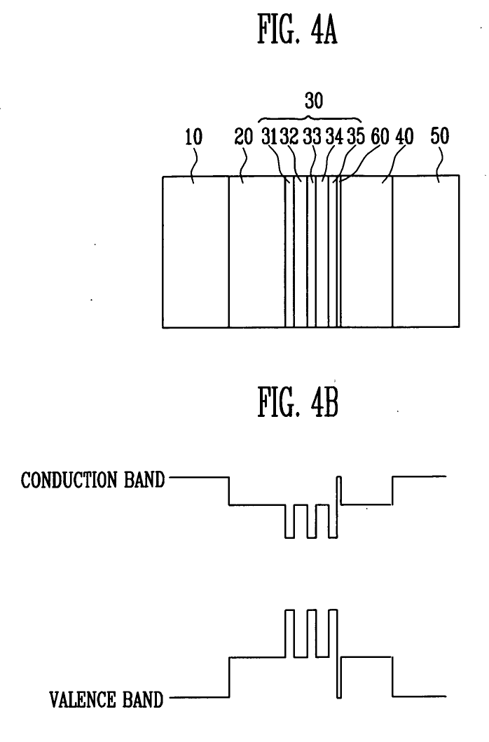

Hereinafter, Embodiment 1 of the present invention will be described in conjunction with FIG. 4. FIG. 4 is a cross-sectional view of a conventional semiconductor laser diode in accordance with a first embodiment of the present invention and an energy band diagram of a semiconductor laser diode corresponding to the cross-sectional view.

Referring to FIG. 4, the semiconductor laser diode of FIG. 4 includes: an active layer 30 having a plurality of quantum well layers 31, 33 and 35 and barrier layers 32 and 34; SCH layers 20 and 40 and clad layers 10 and 50 formed adjacent to the active layer 30; and a tunneling barrier layer 60 formed between the active layer 30 and the SCH layers 20 and 40 to be connected to the at least one quantum well layer 31, 33 or 35 using a material having a band-gap energy larger than the SCH layers 20 and 40. In accordance with the Embodiment 1, the SCH layers 20 and 40 have an energy band gap equal to the barrier layers 32 and 34.

As a result, it is possible to prevent leakage of electrons into a p-clad layer 50 due to the tunneling barrier layer 60, and holes having a large energy entering through the p-clad layer can be smoothly confined in the quantum well layers by the tunneling barrier layer having a sufficiently small thickness through a tunneling effect and a thermionic effect.

In addition, since the tunneling barrier layer 60 is connected to the quantum well layer, it is impossible to exclude a probability of emissive or non-emissive recombination between carriers in the barrier layer or the SCH layer to thereby minimize optical losses. As a result, it is possible to obtain a high optical output and a low threshold current at a high temperature and a high drive current.

Hereinafter, a semiconductor laser diode formed of an InP-based InP/InGaAs/InGaAsP will be described as an example.

Referring to FIG. 4, an SCH (InGaAsP) layer 20, which is doped with n-type dopants, doped with other-type dopants or undoped, is disposed on an n-type clad (n-InP) layer 10, and undoped quantum well layers 31, 33 and 35 (InGaAsP, InGaAs, or InAsP) and barrier layers 32 and 34 (InGaAsP) are sequentially grown on the SCH layer 20 in a multi-quantum well layer structure. Here, the barrier layers 32 and 34 are undoped or doped with n-type dopants (or p-type dopants)

Preferably, in the quantum well structure, a compressive strain of 0.1˜1% is applied to an in-plane surface of bulk in the quantum well, and a tensile strain of 0˜1% is applied to the barrier layer. At this time, the quantum well layer and the barrier layer may be formed to have a thickness of about 3˜15 nm in consideration of an interval of the quantum well and the strain applied to the quantum well and the barrier well within a range not to generate dislocation wherein a lattice constant a of InP is 5.869 Å, and strain is ε, and a critical thickness is about a/2|ε|.

The last quantum well layer 35 and the undoped tunneling barrier layer 60 (InP) are successively grown on the quantum well structure grown as described above, the SCH layer 40 (InGaAsP), which is doped with p-type dopants, doped with other-type dopants or undoped, is disposed on the barrier layer 60, and finally, a p-clad layer 50 (p-InP) is grown on the SCH layer 40. Then, an ohmic contact layer (not shown, for example p-InGaAs) is epitaxially grown on the p-clad layer 50.

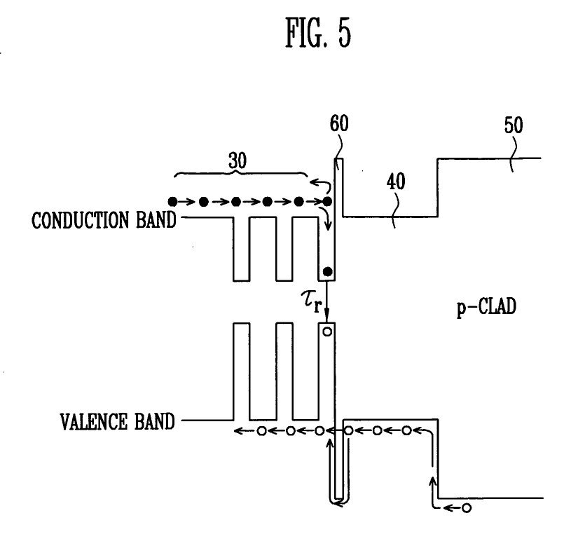

Next, behavior of carriers of the semiconductor laser diode of FIG. 4 will be described in more detail. FIG. 5 is a graph representing behavior of carriers shown as the energy band diagram of the semiconductor laser diode in FIG. 4.

Referring to FIG. 5, electrons introduced from the n-clad layer do not more progress toward the p-clad layer 50 due to the tunneling barrier layer 60 successively formed at end portion of the quantum well, and are blocked by the tunneling barrier layer 60 to be trapped in the quantum well layer. In addition, holes introduced from the p-clad layer 50 may pass through the tunneling barrier layer 60 having a small thickness sufficient to enable tunneling, or pass through the tunneling barrier layer 60 by a thermionic effect and then trapped in the quantum well, thereby performing emissive recombination between carriers within a quantum well region only.

In this case, while the electrons feel high the tunneling barrier layer that the electrons should go over after trapped in a deep quantum well, the holes feel low relatively the tunneling barrier layer in comparison with the electrons, since the holes see the tunneling barrier layer from the SCH layer 40 having an energy value larger than that of the quantum well.

Probability T that a particle (effective mass=m*) having an arbitrary energy E passes through the tunneling barrier layer having a height V₀ and a thickness L is e^{-2KL} (where K=μm*(V0−E)^{1/2}/h; V0>E). Therefore, in order to increase the tunneling probability of the introduced holes through the tunneling barrier layer, since it is important to make the thickness of the barrier layer sufficiently thin, preferably, the tunneling barrier layer has a thickness L of 1˜15 nm.

As can be seen from the formula of tunneling probability of the tunneling barrier layer, it is appreciated that the tunneling barrier layer should have a small thickness in order to increase the tunneling probability and the tunneling probability of the holes is increased when the tunneling barrier layer has a small height. Therefore, another embodiment of the present invention will be described in consideration of the aforementioned phenomenon.

### Embodiment 2

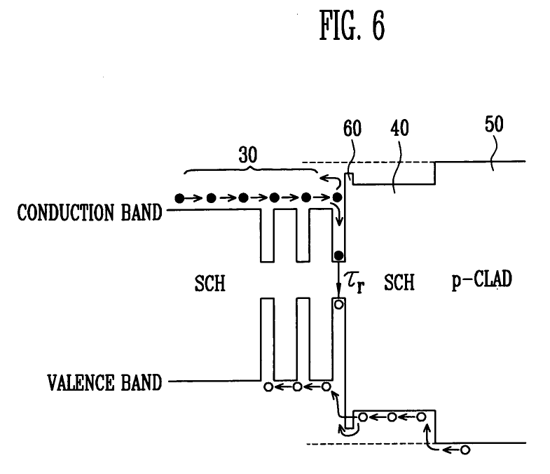

Hereinafter, Embodiment 2 of the present invention will be described in conjunction with FIG. 6. FIG. 6 is a cross-sectional view of a conventional semiconductor laser diode in accordance with a second embodiment of the present invention and an energy band diagram of a semiconductor laser diode corresponding to the cross-sectional view. For convenience of description, differences from Embodiment 1 will be described.

Referring to FIG. 6, in order to lower a height of the barrier layer that the holes feel, the SCH layer 40 epitaxially grown adjacent to the p-clad layer 50 is made of a material having a composition ratio larger than that of an InGaAsP material used in the barrier layer of the quantum well and a band gap energy larger than that of the barrier layer of the quantum well. This is because the material functions to lower the height of the tunneling barrier layer that the holes really feel. In Embodiment 1, the InGaAsP material having the same composition as the barrier layer of the quantum well may be used.

In addition, while Embodiment 1 uses a material for the tunneling barrier layer, for example, InP, Embodiment 2 uses the InGaAsP material having an energy smaller than the band gap energy of the InP and larger than the band gap energy of the SCH layer 40 grown adjacent to the p-clad layer 50. As a result, the holes introduced from the p-clad layer 50 easily go over the tunneling barrier layer having a relatively small energy.

In addition, since a diffusion time that the holes arrive to the tunneling barrier layer after starting from the SCH layer 40 is in proportion to the square of thickness of the SCH layer, preferably, the SCH layer has a small thickness within a range without damaging an optical field confinement effect. Therefore, the SCH layer grown adjacent to the p-clad layer has a thickness (for example, 5˜30 nm) smaller than the thickness (for example, 30˜150 nm) of the SCH layer grown adjacent to the n-clad layer so that the holes introduced from the p-clad layer can arrive at the tunneling barrier layer before the holes lose its entire energy by scattering during long time diffusion.

Meanwhile, the SCH layers at both ends of the quantum well may have a structure that a single InGaAsP material or a plurality of InGaAsP materials having different composition are epitaxially grown in a stepped manner.

As can be seen from the foregoing, the present invention is capable of sufficiently confining holes in the quantum well by a tunneling effect and a thermionic effect, and simultaneously, preventing leakage of electrons and holes, by forming the tunneling barrier layer at an end portion of the quantum well.

In addition, since there is no loss due to non-emissive or emissive recombination between carriers when a barrier layer of the SCH layer or the quantum well does not exist between the quantum well and the tunneling barrier layer, it is possible to obtain a high optical output and a low threshold current even at a high temperature and a high drive current.

Although exemplary embodiments of the present invention have been described with reference to the attached drawings, the present invention is not limited to these embodiments, and it should be appreciated to those skilled in the art that a variety of modifications and changes can be made without departing from the spirit and scope of the present invention.

What is claimed is:

1. An optical semiconductor device comprising:
an active layer having at least one quantum well layer and at least one barrier layer;
a clad layer formed adjacent to the active layer; and
a tunneling barrier layer formed between the active layer and the clad layer to be connected to the quantum well layer and formed of a material having a band-gap energy larger than the barrier layer.

2. The optical semiconductor device according to claim 1, being one of a semiconductor laser diode and a semiconductor light emitting diode.

3. The optical semiconductor device according to claim 1, wherein the tunneling barrier layer has a thickness of 1˜15 nm.

4. The optical semiconductor device according to claim 1, wherein the tunneling barrier layer is formed of a semiconductor layer.

5. The optical semiconductor device according to claim 1, wherein the band gap energy of the tunneling barrier layer is not more than that of the clad layer.

6. An optical semiconductor device comprising:
an active layer having at least one quantum well layer and at least one barrier layer;
an SCH layer and a clad layer formed adjacent to the active layer; and
a tunneling barrier layer formed between the active layer and the SCH layer to be connected to the quantum well layer and formed of a material having a band-gap energy larger than the SCH layer.

7. The optical semiconductor device according to claim 6, being one of a semiconductor laser diode and a semiconductor light emitting diode.

8. The optical semiconductor device according to claim 7, wherein the semiconductor laser diode is one of a buried heterostructure (BH) laser diode, a ridge laser diode and a spot size converter.

9. The optical semiconductor device according to claim 6, wherein the tunneling barrier layer has a thickness of 1˜15 nm.

10. The optical semiconductor device according to claim 6, wherein the tunneling barrier layer is formed of a semiconductor layer.

11. The optical semiconductor device according to claim 6, wherein the band gap energy of the tunneling barrier layer is not more than that of the clad layer.
